(19) United States
(12) Patent Application Publication
(10) Pub. No.: US 2009/0212834 A1
(43) Pub. Date: Aug. 27, 2009

(54) SEQUENCING CONTROL CIRCUIT

(75) Inventor: XIANG ZHANG, Shenzhen City (CN)

Correspondence Address: PCE INDUSTRY, INC.;ATT. Steven Reiss, 458 E. LAMBERT ROAD, FULLERTON, CA, 92835, US

(73) Assignees: HONG FU JIN PRECISION INDUSTRY (ShenZhen) CO., LTD., Shenzhen City (CN); HON HAI PRECISION INDUSTRY CO., LTD., Tu-Chung (TW)

(21) Appl. No.: 12/118,652

(22) Filed: May 9, 2008

(30) Foreign Application Priority Data
Feb. 22, 2008 (CN) 200820300263.4

(51) Int. Cl. H03L 7/00

(52) U.S. Cl. 327/143

(57) ABSTRACT

A sequencing control circuit includes an electronic component configured for controlling a signal output to a motherboard, and input voltages being input to the sequencing control circuit. The input voltages are connected to an input terminal of the electronic component. The electronic component includes a preset threshold and input voltage requirements. The electric component is configured such that only when all of the required input voltages rise to their peak values and the voltage of the input terminal of the electronic component reaches the threshold. The electronic component is triggered, and an output terminal of the electronic component outputs a high level signal to the motherboard.

### BACKGROUND

1. Technical Field

The present invention relates to sequencing control circuits, and more particularly to a sequencing control circuit for a motherboard of a computer.

2. Description of Related Art

Chipset are very important for computer motherboards. Chipsets usually include a south bridge chip and a north bridge chip. The south bridge chip generally communicates with peripheral components, such as PCI interfaces, IDE controllers for hard disk drives and DVD ROM drives, USB controllers, floppy disk drives, keyboards, and mice, and so on. When the south bridge chip is accidentally damaged due to abnormal sequencing signals, these peripheral components cannot work normally. The north bridge chip generally communicates with the computer processor and controls interaction with memory, the Peripheral Component Interconnect (PCI) bus, Level 2 cache, and all Accelerated Graphics Port (AGP) activities. The south bridge chip and the north bridge chip are all provided power by a power supply of the computer. However, for different kinds of power supplies, there are different sequences for different voltages of the power supply rising to their peak values. Thus, the south bridge chip or the north bridge chip may be in a state of sequencing confusion when the power supply is replaced.

What is needed, therefore, is a sequencing control circuit which can adapt to different power supplies to ensure normal sequencing for a chipset of a motherboard.

### SUMMARY

A sequencing control circuit includes an electronic component configured for controlling a signal output to a motherboard, and input voltages being input to the sequencing control circuit. The input voltages are connected to an input terminal of the electronic component. The electronic component includes a preset threshold and input voltage requirements. The electric component is configured such that only when all of the required input voltages rise to their peak values and the voltage of the input terminal of the electronic component reaches the threshold. The electronic component is triggered, and an output terminal of the electronic component outputs a high level signal to the motherboard.

Other advantages and novel features of the present invention will become more apparent from the following detailed description of exemplary embodiments when taken in conjunction with the accompanying drawings, in which:

### BRIEF DESCRIPTION OF THE DRAWINGS

FIG. 1 is a circuit diagram of a sequencing control circuit in accordance with an exemplary embodiment of the present invention;

FIG. 2 is a diagram of a chip of a motherboard in which the sequencing control circuit of FIG. 4 is used to ensure a +3.3V voltage terminal is input to the chip first;

FIG. 3 is a sequencing graph of FIG. 2;

FIG. 4, labeled as prior art, is a graph of voltage rise times of a conventional power supply;

FIG. 5, labeled as prior art, is a graph of voltage rise times of another conventional power supply; and

FIG. 6, labeled as prior art, is a diagram of a conventional arrangement of a chip on a motherboard, in which different voltage terminals control the chip.

### DETAILED DESCRIPTION OF THE INVENTION

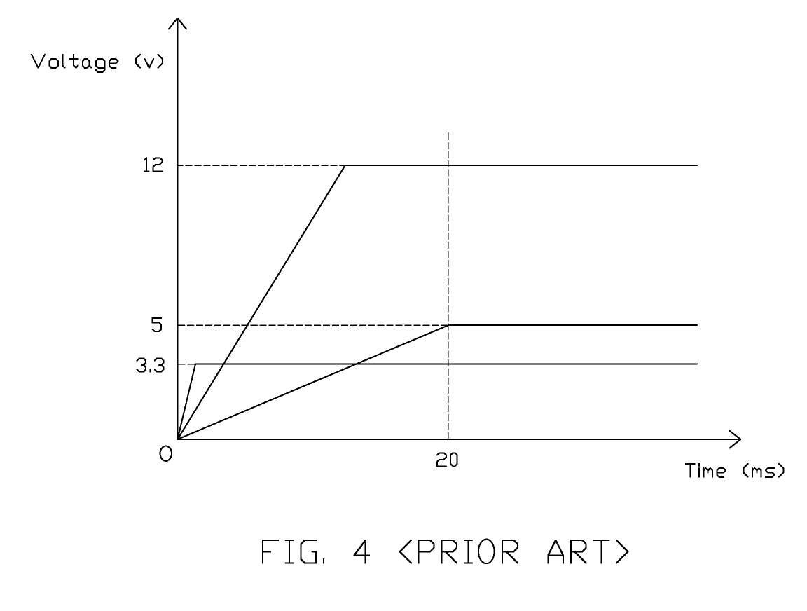

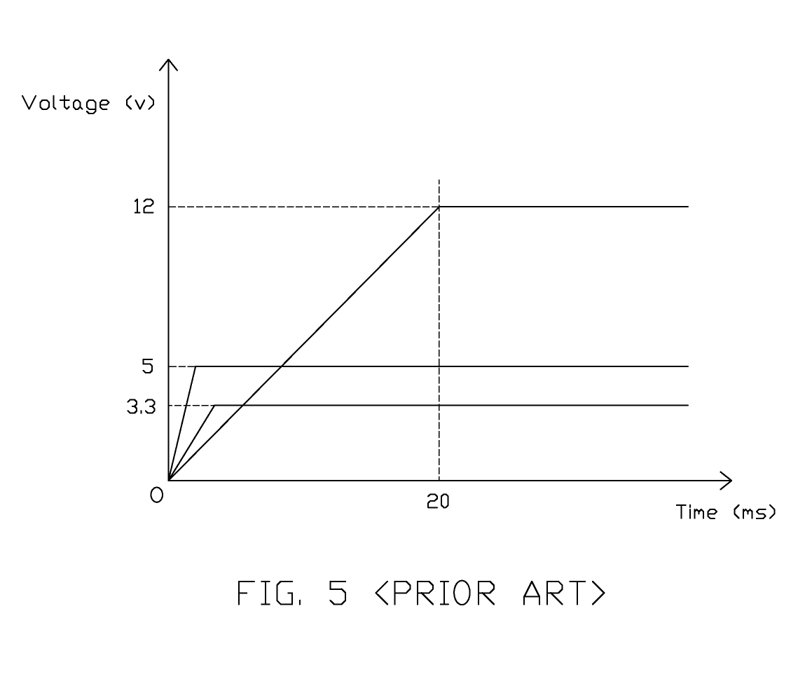

Previously, as shown in FIG. 4, different voltages of one power supply rising to their peak values in that order. The +3.3V voltage rises to its peak values first, the +12V voltage rises to its peak values secondly, the +5V voltage rises to its peak values thirdly. FIG. 5 shows another previous sequence of different voltages +5V, +3.3V, +12V of another power supply rising to their peak values in that order.

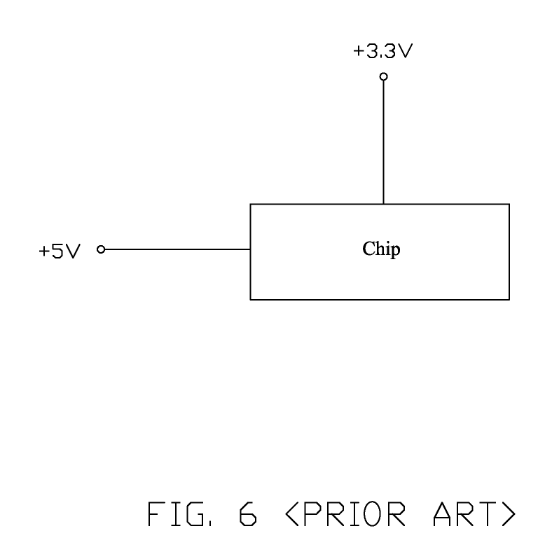

Referring to FIG. 6, on a motherboard, high level signals, such as the +5V voltage and the +3.3V voltage, are supplied to a chip to power it. But it is expected that the +3.3V voltage be supplied to the chip first. Thus, the power supply of FIG. 5 cannot be used, or the chip would be powered up out of sequence.

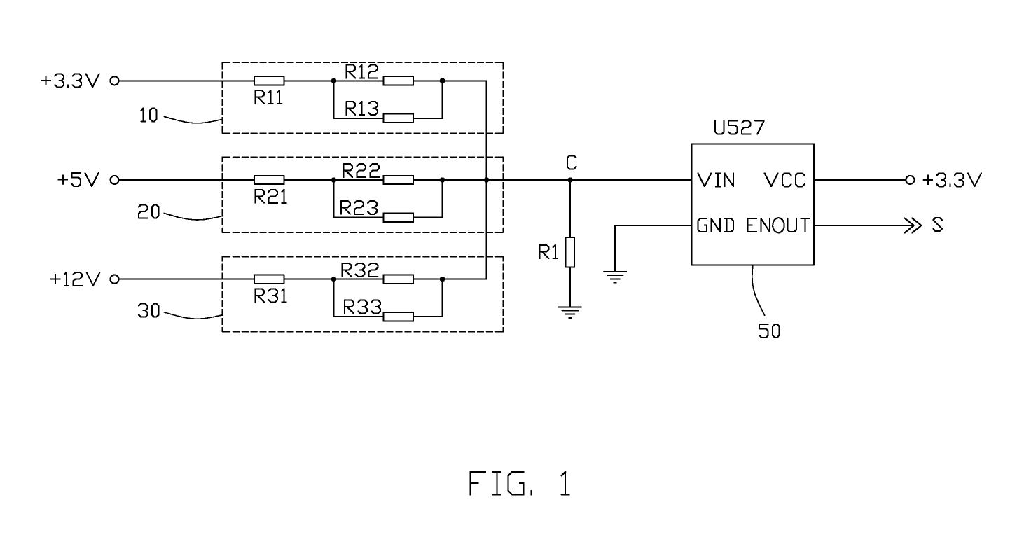

Referring to FIG. 1, a sequencing control circuit of an exemplary embodiment of the present invention includes a first circuit 10, a second circuit 20, a third circuit 30, a resistor R1, and a chip 50 (type No. U527).

One terminal of a resistor R11 of the first circuit 10 is connected to a first voltage terminal +3.3V. The other terminal of the resistor R11 is connected to one terminal of parallel connected resistors R12, R13 of the first control circuit 10. The other terminal of the parallel connected resistors R12, R13 is connected to one terminal C of the resistor R1. The other terminal of the resistor R1 is connected to ground. One terminal of a resistor R21 of the second circuit 20 is connected to a second voltage terminal +5V. The other terminal of the resistor R21 is connected to one terminal of parallel connected resistors R22, R23 of the second circuit 20. The other terminal of the parallel connected resistors R22, R23 is connected to the terminal C of the resistor R1. One terminal of a resistor R31 of the third circuit 30 is connected to a third voltage terminal +12V. The other terminal of the resistor R31 is connected to one terminal of parallel connected resistors R32, R33 of the third circuit 30. The other terminal of the parallel connected resistors R32, R33 is connected to the terminal C of the resistor R1. The terminal C is also connected to the pin VIN of the chip 50.

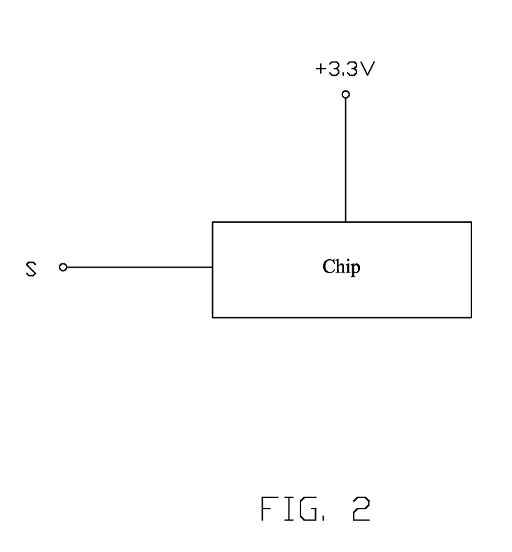

In this embodiment approximate resistances are as follows: R1 is 20 ohm, R11 is 240K ohm, R12 and R13 are both 12K ohm, R21 is 402K ohm, R22 and R23 are both 10K ohm, R31 is 1.21M ohm, and R32 and R33 are both 160K ohm. A threshold of the pin VIN of the chip 50 is set to +0.6V. The voltage level at the terminal C can only reach +0.6V when voltage at the first voltage terminal is +3.3V, voltage at the second voltage terminal is +5V, and voltage at the third voltage terminal +12V. When the input voltage reaches +0.6V, the chip 50 is triggered, and the pin ENOUT outputs a high level signal “S” (+5V voltage) to a chip of the motherboard (as shown in FIG. 2). Thus, the signal “S” is always input to the chip of the motherboard finally because the signal “S” must be output until the first voltage terminal +3.3V, the second voltage terminal +5V, and the third voltage terminal +12V all rise to their peak values. The +3.3V voltage will first be provided to the chip of the motherboard, and the high level signal “S” is provided to the chip of the motherboard secondly. When the input voltage is below the threshold +0.6V, the chip 50 is not triggered.

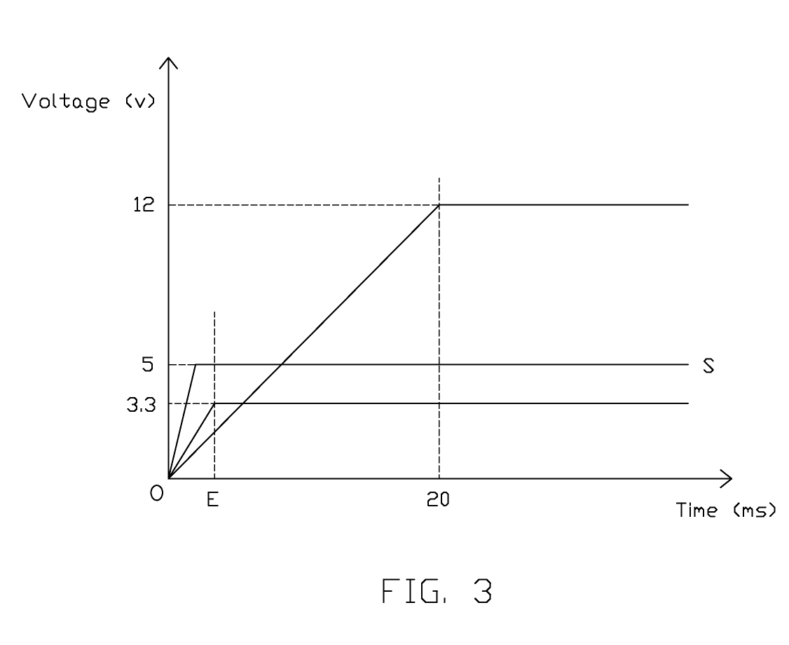

Referring to FIG. 3, at time point E, the first voltage terminal +3.3V and the second voltage terminal +5V have risen to their peak values, but the third voltage terminal +12V has not yet reached its peak value. At time E voltage level of the terminal C is lower than +0.6V, and the pin ENOUT of the chip 50 cannot output the high level signal “S” out of sequence. After a short time and the third voltage terminal +12V rises to the peak value, the terminal C can then output +0.6V, and the chip 50 outputs the high level signal “S” to the motherboard after the +3.3V has been provided.

The chip 50 can be replaced by other chips. If threshold of another chip is different from the threshold of the chip 50, the first circuit, the second circuit, the third circuit and the resistor are changed so that the input voltage of the other chip reaches the threshold.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A sequencing control circuit for controlling a motherboard, the sequencing control circuit comprising:
an electronic component configured for controlling a signal output to the motherboard; and
input voltages being input to the sequencing control circuit, the input voltages connected to an input terminal of the electronic component;
wherein the electronic component comprises a preset threshold and input voltage requirements, the electric component is configured such that only when all of the required input voltages rise to their peak values and the voltage of the input terminal of the electronic component reaches the threshold, the electronic component is triggered, and an output terminal of the electronic component outputs a high level signal to the motherboard.

2. The sequencing control circuit as described in claim 1, wherein a resistor is connected between the input voltages of the sequencing control circuit and ground.

3. The sequencing control circuit as described in claim 1, wherein a plurality of circuits is respectively connected between the input voltages of the sequencing control circuit and the input terminal of the electronic component.

4. The sequencing control circuit as described in claim 3, wherein each circuit comprises a resistor and two parallel connected resistors serial connecting to the resistor.

5. The sequencing control circuit as described in claim 1, wherein the input voltages are respectively +3.3V, +5V, and +12V.

6. The sequencing control circuit as described in claim 1, wherein the electronic component is a chip.

7. A method for controlling the sequencing of a motherboard, the method comprising of providing:
the motherboard supplied with a first voltage and then supplied with a second voltage secondly, the first voltage being different from the second voltage;
wherein the first and second voltages being input to a control circuit, the control circuit outputting a threshold voltage when the first voltage and second voltage provided simultaneously; and
the control circuit connected to a chip, the chip to be triggered by the threshold voltage and output a third voltage to the circuit instead of the second voltage, the third voltage being equal to the second voltage.

8. The method as described in claim 7, wherein the control circuit comprises a first circuit and a second circuit, the first voltage being input to the first circuit, the second voltage being input to the second circuit.

9. The method as described in claim 8, wherein the first circuit and the second circuit both comprise a resistor and two parallel connected resistors serial connecting to the resistor.

10. The method as described in claim 7, wherein a resistor is connected between the control circuit and ground.

11. A method for ensuring normal sequencing of a motherboard, the method comprising:
providing:
three input voltages of the motherboard rising to their peak values respectively;
three circuits connecting three input voltages respectively to a common node for outputting a particular voltage; and
the particular voltage being input to a chip for triggering the chip;
wherein the chip outputs a signal to the motherboard, the signal is sent only after three input voltages of the motherboard have risen to their peak values for ensuring normal sequencing of the motherboard.

12. The method as described in claim 10, wherein three input voltages of the motherboard are respectively +3.3V, +5V and +12V.

13. The method as described in claim 10, wherein each circuit is consisted of a resistor and two parallel connected resistors serial connecting to the resistor.
